(19) United States
(12) Patent Application Publication
(10) Pub. No.: US 2025/0261493 A1
(43) Pub. Date: Aug. 14, 2025

(54) DISPLAY PANEL, METHOD OF MANUFACTURING THE SAME, AND TERMINAL DEVICE

(71) Applicant: WUHAN CHINA STAR OPTOELECTRONICS SEMICONDUCTOR DISPLAY TECHNOLOGY CO., LTD., Wuhan (CN)

(72) Inventors: Weilai LIU, Wuhan (CN); Liang SUN, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 19/190,786

(22) Filed: Apr. 27, 2025

Related U.S. Application Data
(63) Continuation of application No. PCT/CN2024/114448, filed on Aug. 26, 2024.

(30) Foreign Application Priority Data
Nov. 30, 2023 (CN) 202311641682.X

(51) Int. Cl. H10H 29/80; H01L 25/075; H10H 29/01; H10H 29/85; H10H 29/855

(52) U.S. Cl. CPC H10H 29/8321; H01L 25/0753; H10H 29/032; H10H 29/0364; H10H 29/8552; H10H 29/857

(57) ABSTRACT

A display panel includes an integrated circuit substrate, a light-emitting device layer and a second electrode. The light-emitting device layer includes light-emitting devices disposed respectively in light-emitting areas and insulating layers disposed respectively in insulating barrier areas, and each insulating barrier area is disposed between two adjacent light-emitting areas. Each insulating layer has opposite ends respectively connected to the second electrode and the integrated circuit substrate and each light-emitting device is surrounded by several insulating layers, so that the several insulating layers, the second electrode and the integrated circuit substrate together form a closed accommodating chamber for accommodating the light-emitting device.

### CROSS-REFERENCE TO RELATED APPLICATIONS

This application is a continuation of International Application No. PCT/CN2024/114448, filed on Aug. 26, 2024, which claims priority to Chinese Patent Application No. 202311641682.X, filed on Nov. 30, 2023. The disclosures of the abovementioned applications are incorporated herein by reference in their entireties.

### TECHNICAL FIELD

The present application relates to display technologies, and in particular to a display panel, a method of manufacturing a display panel, and a terminal device.

### BACKGROUND

Generally, in a display panel manufactured by an etching process, each light-emitting device and each light-emitting area are defined by etched step structures. However, the sidewalls of the etched step structures may easily form leakage channels, which may result in large leakage current, thereby reducing the performance and the luminous efficiency of the display panel. In addition, the etched step structures may result in an increased distance between two adjacent light-emitting devices, which is not conducive to achieving an increased pixel density of the display panel.

### SUMMARY

According to some embodiments of the present application, a display panel includes an integrated circuit substrate, a light-emitting device layer and a second electrode. The integrated circuit substrate includes a first substrate and a plurality of first electrodes arranged at intervals on the first substrate. The light-emitting device layer is disposed on the integrated circuit substrate, and has a plurality of light-emitting areas arranged in an array and a plurality of insulating barrier areas each disposed between two adjacent ones of the light-emitting areas. The light-emitting device layer includes a plurality of light-emitting devices each disposed in one of the light-emitting areas and electrically connected to one of the first electrodes. The second electrode is disposed on a side of the light-emitting device layer away from the first substrate and electrically connected to the light-emitting devices. A plurality of insulating layers are disposed respectively in the insulating barrier areas. Each of the insulating layers has opposite ends respectively connected to the second electrode and the integrated circuit substrate, and each of the light-emitting devices is surrounded by ones of the insulating layers, so that the ones of the insulating layers, the second electrode and the integrated circuit substrate together form a closed accommodating chamber for accommodating the each of the light-emitting devices, and every two adjacent ones of the light-emitting devices are insulated from each other.

According to some embodiments of the present application, a method of manufacturing the above display panel includes: providing the integrated circuit substrate and the light-emitting device layer, where the integrated circuit substrate includes the first substrate and the plurality of first electrodes arranged at intervals on the first substrate; forming a first bonding layer on a surface of the integrated circuit substrate and a second bonding layer on a surface of the light-emitting device layer, and bonding the first bonding layer and the second bonding layer to each other to obtain a bonding metal layer; defining the plurality of light-emitting areas and the plurality of insulating barrier areas of the light-emitting device layer, where each of the light-emitting areas is surrounded by ones of the insulating barrier areas; performing ion implantation on each of the insulating barrier areas from a side of the light-emitting device layer, so that at least respective parts of the light-emitting device layer in the insulating barrier areas are converted into the plurality of insulating layers and the plurality of light-emitting devices respectively disposed in the light-emitting areas are obtained, where every two adjacent ones of the light-emitting devices are insulated from each other by one of the insulating layers; and forming a layer of transparent conductive material on an entire surface of the light-emitting device layer away from the integrated circuit substrate, to obtain the second electrode.

According to some embodiments of the present application, a terminal device includes the above-mentioned display panel.

### BRIEF DESCRIPTION OF THE DRAWINGS

FIG. 1 schematically shows a cross-section of a display panel according to one or more embodiments of the present application.

FIG. 2A to FIG. 2G schematically show respective processes of a method of manufacturing a display panel according to one or more embodiments of the present application.

FIG. 3 is a flowchart of a method of manufacturing a display panel according to one or more embodiments of the present application.

FIG. 4 is a schematic block diagram of a terminal device including a display panel according to one or more embodiments of the present application.

### DETAILED DESCRIPTION

Some embodiments of the present application will be described in detail below with reference to the accompanying drawings. The embodiments are described for illustrative purposes only and are not intended to limit the present application.

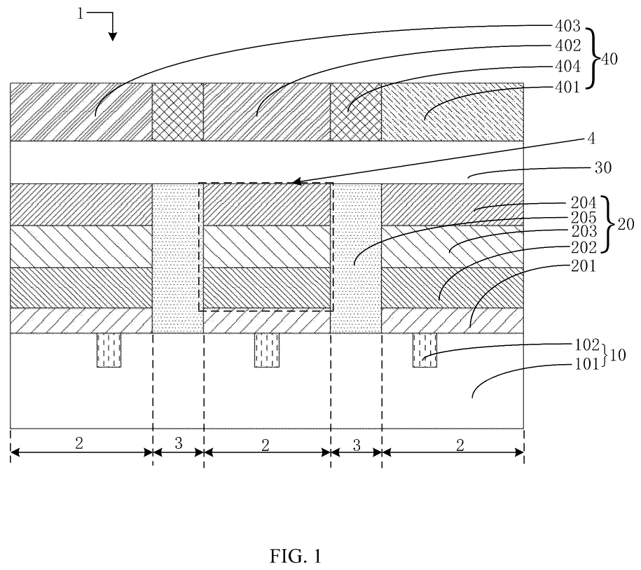

In FIG. 1, the display panel 1 provided in the present application includes an integrated circuit substrate 10, a light-emitting device layer 20, and a second electrode 30. The integrated circuit substrate 10 includes a first substrate 101 and a plurality of first electrodes 102 arranged at intervals on the first substrate 101. The light-emitting device layer 20 is disposed on the integrated circuit substrate 10. The light-emitting device layer 20 includes light-emitting areas 2 arranged in an array, and insulating barrier areas 3 arranged between two adjacent ones of the light-emitting areas 2. The light-emitting device layer 20 includes a light-emitting device 4 arranged in the light-emitting area 2. The first electrodes 102 are electrically connected to a bonding metal layer 201, the second electrode 30 is disposed on a side of the light-emitting device layer 20 away from the first substrate, and the second electrode 30 is electrically connected to the light-emitting device 4. The insulating barrier area 3 of the light-emitting device layer 20 is provided with an insulating layer 205, the insulating layer 205 is disposed around the light-emitting device 4, and the two ends of the insulating layer 205 are respectively connected to the second electrode 30 and the integrated circuit substrate 10 to form a closed accommodating chamber, the light-emitting device 4 is arranged in the closed accommodating chamber, and the two adjacent ones of light-emitting devices 4 are insulated.

The light-emitting device 4 includes a first doped semiconductor layer 202, a light emitting layer 203, and a second doped semiconductor layer 204 sequentially stacked on the integrated circuit substrate 10.

The second electrode 30 may be made of a transparent material.

The second electrode 30 may be disposed as a whole surface, or the second electrode 30 may be disposed in a grid shape.

In this embodiment, an insulating barrier area 3 is provided around the light-emitting area 2, and an insulating layer 205 for insulating two adjacent ones of light-emitting devices 4 is provided in the insulating barrier area 3. Two ends of the insulating layer 205 are respectively connected to the second electrode 30 and the integrated circuit substrate 10 to form a closed accommodating chamber. The position of the light-emitting device 4 is defined by the closed accommodating chamber. The insulating layer 205 can reduce the lateral leakage current between two adjacent ones of light-emitting devices 4, thereby improving the luminous efficiency of the display panel.

The technical solution of the present application is now described in conjunction with specific embodiments.

The display panel 1 of the present application may be an MLED display panel, and a Micro LED display panel is used here as an example for illustration. Other display panels 1 are also included in the protection scope of the present application. The drawings of the present application only use the blue light emitting layer 203 as an example for illustration. For white light emitting layers or light-emitting layers 203 of other colors, the filter layer 40 may be changed for suitability to maintain the light-emitting effect.

In one or more embodiments, the ratio of the width of the insulating barrier area 3 to the width of the light emitting area 2 is in a range of 2:9 to 4:9.

Preferably, the ratio of the width of the insulating barrier area 3 to the width of the light emitting area 2 may be 2:9, 3:9, or 4:9.

The width of the insulating barrier area 3 refers to a section width of the insulating barrier area 3 in any longitudinal section; the width of the light-emitting region 2 refers to the section width of the light-emitting region 2 in the above longitudinal section.

It is understandable that, since the width of the insulating barrier area 3 can be made very small through ion implantation, the width ratio between the insulating barrier area 3 and the adjacent light-emitting device 4 is reduced, thereby increasing the pixel density.

In this embodiment, the width of the insulating barrier area 3 is reduced by means of ion implantation, thereby increasing the arrangement density of the light-emitting devices 4.

In one or more embodiments, referring to FIG. 1, the insulating layer 205 is disposed at least through the light-emitting device layer 20 and the bonding metal layer 201 in the film thickness direction.

The insulating layer 205 may be disposed only in the light-emitting device layer 20 and the bonding metal layer 201.

The insulating layer 205 may also be partially disposed in the integrated circuit substrate 10.

The insulating layer 205 at least being disposed through the light-emitting device layer 20 and the bonding metal layer 201 means that, in the film thickness direction, the thickness of the insulating layer 205 is greater than or equal to the thickness of the light-emitting device layer 20 and the bonding metal layer 201 in the insulating barrier area 3.

The surface of the insulating layer 205 away from the integrated circuit substrate 10 may be flush with the surface of the light-emitting device layer 20 away from the integrated circuit substrate 10.

It can be understood that the insulating layer 205 needs to be disposed through the light-emitting device layer 20, so that two adjacent ones of light-emitting devices 4 cannot be connected to each other through any of the bonding metal layer 201, the first doped semiconductor layer 202, the light-emitting layer 203, or the second doped semiconductor layer 204, thus the two adjacent ones of light-emitting devices 4 are insulated. In addition, the insulating layer 205 is formed by ion implantation, and there will be no leakage current caused by etching damage.

In this embodiment, the insulating layer 205 at least penetrates the light-emitting device layer 20, so that two adjacent ones of light-emitting devices 4 are insulated, further reducing the lateral leakage current between the two adjacent ones of light-emitting devices 4, thereby improving the luminous efficiency.

In one embodiment, as shown in FIG. 1, the MLED further comprises a filter layer 40 disposed on a side of the second electrode 30 away from the light-emitting device layer 20, the filter layer 40 comprising filter patterns arranged at intervals and a black matrix 404. The light-emitting layer 203 is a blue light emitting layer, the filter patterns comprise red color resist 401, green color resist 402, and a light-transmitting pattern 403 arranged at intervals, and the light-transmitting pattern 403 is made of a transparent material, or the light-emitting layer 203 is a white light emitting layer, the filter patterns comprise a red color resist 401, a green color resist 402, and a blue color resist arranged at intervals.

The material of the red color resist 401 includes cadmium selenide, perovskite or indium phosphide, and the full width at half maximum (FWHM) of the red-light transmittance of the material of the red color resist 401 ranges from 30 nanometers to 50 nanometers. The material of the green color resist 402 includes cadmium selenide, perovskite or indium phosphide, and the FWHM of the green color resist 402 ranges from 30 nanometers to 50 nanometers. The material of the blue color resist includes cadmium selenide, perovskite or indium phosphide, and the FWHM of the blue color resist ranges from 30 nanometers to 50 nanometers.

When the light-emitting layer 203 is a blue light emitting layer, the material of the light-transmitting pattern 403 includes any one of polyacrylate resin, polyimide resin, or silica-based inorganic material.

The black matrix 404 may be made of a black epoxy resin material.

In one or more embodiments, the filter pattern is disposed corresponding to the light-emitting device 4, and the black matrix 404 is disposed corresponding to the insulating layer 205, and the black matrix 404 and the insulating layer 205 are overlapped with each other in the film thickness direction.

The black matrix 404 and the insulating layer 205 being overlapped means that, the orthographic projection of the black matrix 404 on the first substrate 101 overlaps the orthographic projection of the insulating layer 205 on the first substrate 101.

It can be understood that by disposing the black matrix 404 to be overlapped with the insulating layer 205, the shielding of the black matrix 404 in the light exiting direction of the light-emitting device 4 is reduced, thereby enhancing the light exiting intensity.

In one embodiment, the bonding metal layer 201 includes a first portion abutting against the integrated circuit substrate 10 and a second portion abutting against the light-emitting device layer 20, and the first portion and the second portion are made of the same material. For example, the bonding metal layer 201 includes a first bonding layer and a second bonding layer which are stacked, the first bonding layer is disposed on a surface of the integrated circuit substrate 10 facing the light-emitting device layer 20, the second bonding layer is disposed on a surface of the light-emitting device layer 20 facing the integrated circuit substrate 10, and the first bonding layer and the second bonding layer are made of the same material.

It can be understood that the bonding metal layer 201 includes a first part and a second part, and the first part and the second part are made of the same material. In the process of forming the bonding metal layer, the first bonding layer disposed on the surface of the integrated circuit substrate 10 facing the light-emitting device layer 20 forms the first part, and the second bonding layer disposed on the surface of the light-emitting device layer 20 facing the integrated circuit substrate 10 forms the second part. Since the first bonding layer and the second bonding layer are made of the same material, the process is simplified and the cost is reduced.

In one embodiment, the material of the second doped semiconductor layer 204 includes at least one of gallium nitride, aluminum gallium nitride, and aluminum indium gallium nitride, the material of the first doped semiconductor layer 202 includes gallium nitride, and the material of the light-emitting layer 203 includes a quantum well material of indium gallium nitride or gallium nitride.

In one embodiment, the bonding structure in the bonding metal layer 201 includes at least one of gold-gold bonding, gold-tin bonding, gold-indium bonding, titanium-titanium bonding, and copper-copper bonding.

In one embodiment, the thickness of the bonding metal layer 201 is in a range of 0.1 micrometers to 3 micrometers.

In one embodiment, the bonding metal layer 201 may also be used to reflect light emitted from the light-emitting device 4 disposed above it, thereby enhancing light emitting. In one embodiment, the insulating layer 205 includes at least one of helium ions, carbon ions, nitrogen ions, oxygen ions, and fluorine ions.

It can be understood that by doping the above-mentioned ions which can increase the resistance of the light-emitting device layer 20 in the insulating barrier area 3, the light-emitting device layer 20 in the insulating barrier area 3 is transformed into an insulating layer 205 with insulating properties, and the insulating layer 205 is used to realize the insulation setting between two adjacent ones of light-emitting devices 4 and define the setting position of the light-emitting device 4.

In one embodiment, a first periodic stress adjustment layer and a first current diffusion layer are further disposed between the first doped semiconductor layer 202 and the light-emitting layer 203, and a second periodic stress adjustment layer and a second current diffusion layer are further disposed between the second doped semiconductor layer 204 and the light-emitting layer 203. The first periodic stress adjustment layer and the second periodic stress adjustment layer are used to reduce the stress inside the light-emitting device layer 20, the first current diffusion layer is used to reduce the contact resistance between the first doped semiconductor layer 202 and the light-emitting layer 203, and the second current diffusion layer is used to reduce the contact resistance between the second doped semiconductor layer 204 and the light-emitting layer 203.

It can be understood that the periodic stress adjustment layer and the current diffusion layer are used to enable the first doped semiconductor layer 202 and the second doped semiconductor layer 204 to better transmit electrons and holes to the light emitting layer 203.

In one embodiment, the second electrode 30 is made of a transparent conductive oxide material.

The second electrode 30 is made of any one of indium tin oxide, aluminum-doped zinc oxide, and a composite of nickel oxide and gold.

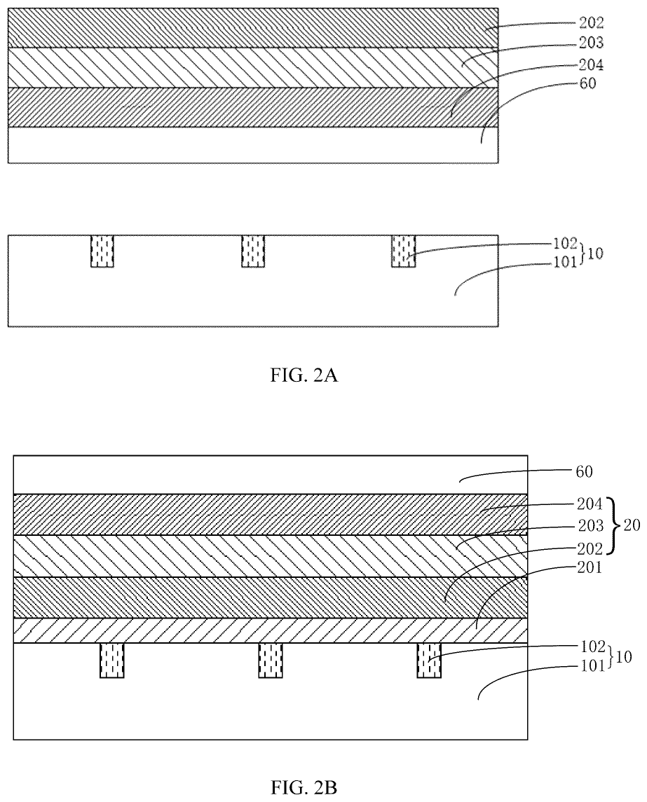

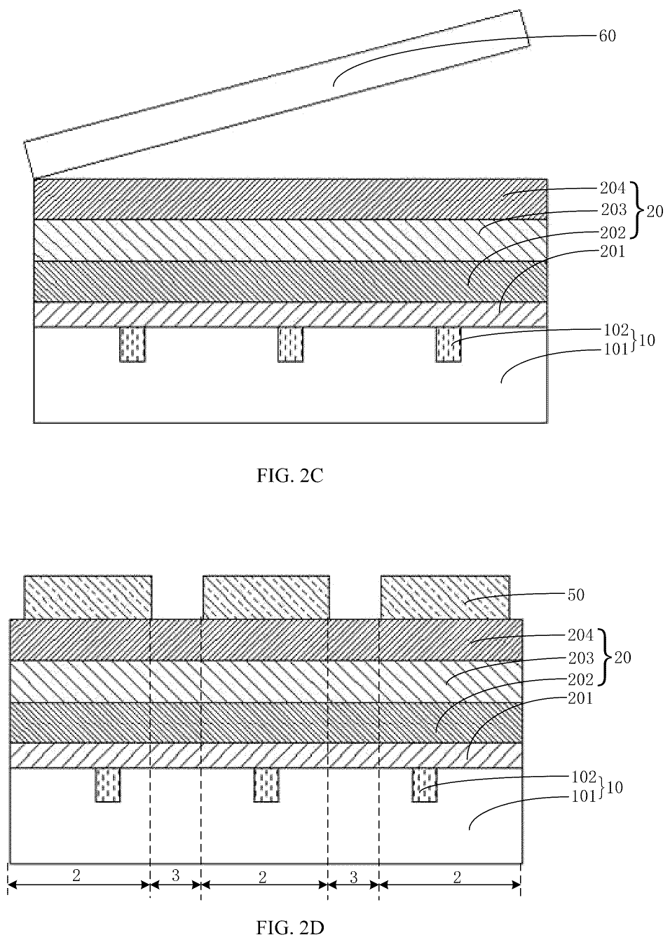

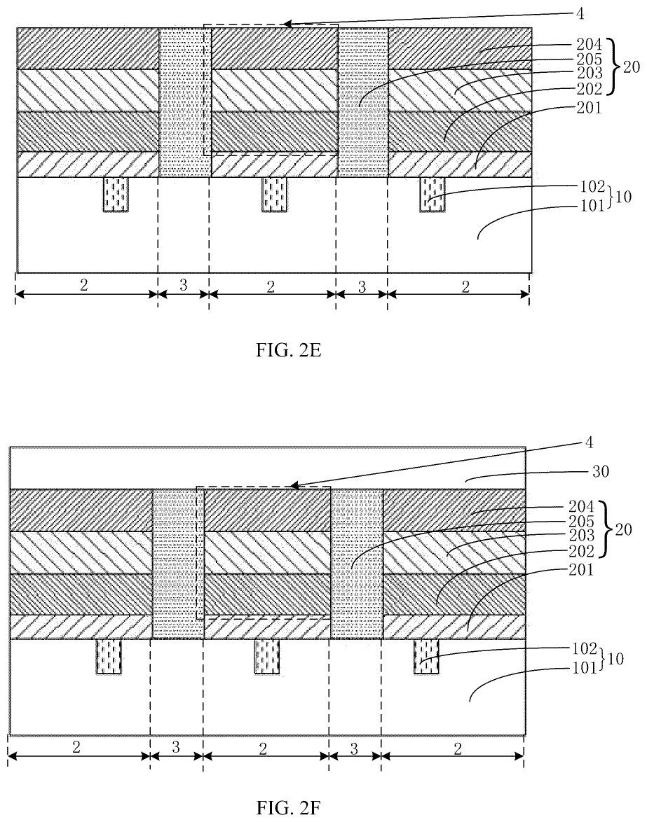

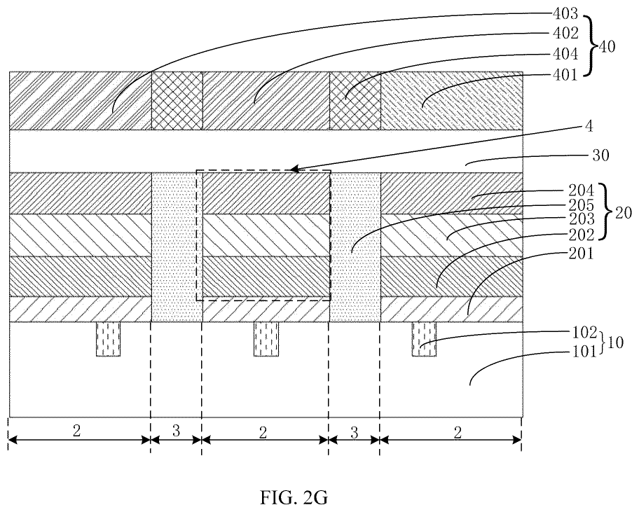

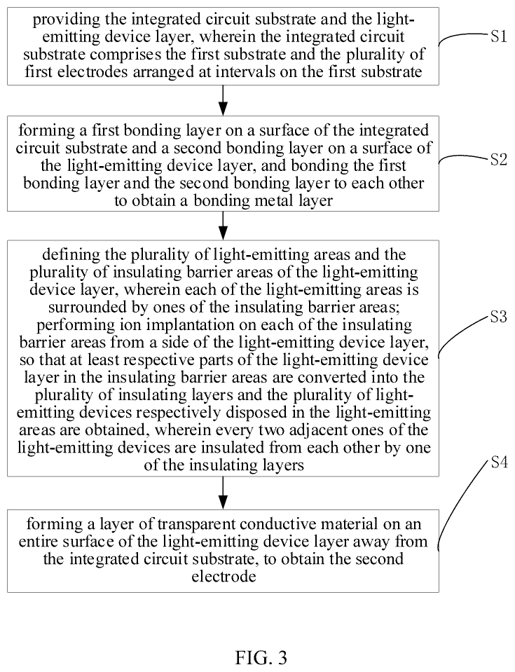

As shown in FIG. 2A to FIG. 2G and FIG. 3, an embodiment of the present application provides a method of manufacturing a display panel 1, which is used to manufacture the display panel I described in any of the above embodiments. The method includes:
S1: providing an integrated circuit substrate 10 and a light-emitting device layer 20, the integrated circuit substrate 10 includes a first substrate and a plurality of first electrodes arranged at intervals on the first substrate;
S2: forming a first bonding layer on a surface of the integrated circuit substrate 10, forming a second bonding layer on a surface of the light-emitting device layer 20, and bonding the first bonding layer and the second bonding layer opposite to each other to obtain the bonding metal layer 201;
S3: defining a plurality of light-emitting areas 2 and a plurality of insulating barrier areas 3 of the light-emitting device layer 20, a light-emitting device is disposed in each of the light-emitting areas and each of the insulating barrier areas is disposed surrounding one of the light-emitting areas, and performing an ion implantation on the insulating barrier areas 3 from one side of the light-emitting device layer 20, so that at least the light-emitting device layer 20 in the insulating barrier areas 3 is transformed into an insulating layer 205 insulating the two adjacent ones of the light-emitting devices 4;
S4: forming a layer of transparent conductive material on the entire surface of the light-emitting device layer 20 away from the integrated circuit substrate 10 to obtain the second electrode 30.

For step S1, as shown in FIG. 2A, the light-emitting device layer 20 includes a second substrate 60, a second doped semiconductor layer 204 disposed on one side of the second substrate 60, a light-emitting layer 203, and a first doped semiconductor layer 202.

For step S2, as shown in FIG. 2B to FIG. 2C, the integrated circuit substrate 10 and the light-emitting device layer 20 in step S1 are connected through the bonding metal layer 201, and the first bonding layer and the second bonding layer can be bonded by but not limited to welding. For step S3, please refer to FIG. 2D and FIG. 2E; for step S4, please refer to FIG. 2F.

In one embodiment, as shown in FIG. 2B, the light-emitting device layer 20 in step S1 further includes a second substrate 60, and a second doped semiconductor layer 204, a light-emitting layer 203, and a first doped semiconductor layer 202 which are disposed in sequence on a surface of the second substrate 60, and the material of the second substrate 60 includes at least one of gallium nitride, aluminum nitride, silicon, and silicon carbide.

It can be understood that, as shown in FIG. 2C, the second substrate 60 will be removed after the bonding metal layer 201 is obtained in step S2, and the second substrate 60 can be removed by a laser lift-off process or wet chemical etching.

In one embodiment, the step of performing ion implantation on the insulating barrier area 3 further includes: by controlling the conditions during ion implantation, such as ion type, dose, ion energy, implantation angle, etc., the electrical property of the insulating barrier area 3 is transformed from conductivity to insulation.

It can be understood that, taking the first doped semiconductor layer 202 as an example, when the thickness of the first doped semiconductor layer 202 is in a range of 0.1 micron to 20 microns, when the depth of ion implantation needs to penetrate the first doped semiconductor layer 202, the energy of ion implantation is preferably 10 keV to 500 keV, and the duration of ion implantation is preferably 1 minute to 10 minutes.

In one embodiment, as shown in FIG. 2D, a photoresist material is coated on the surface of the second doped semiconductor layer 204 away from the integrated circuit substrate 10, and the photoresist material is patterned using an exposure and development process to form a photoresist structure 50, so that the photoresist structure 50 located in the light-emitting area 2 is arranged opposite to a light-emitting device 4.

After the step of performing ion implantation on the insulating barrier area 3, the photoresist structure 50 is removed.

In one embodiment, after step S4 in FIG. 2G, the method further includes step S5 (not shown in FIG. 2G): forming a filter layer 40 on a side of the second electrode 30 away from the integrated circuit substrate 10.

The filter layer 40 may include a red color resist 401, a green color resist 402, a light-transmitting pattern 403, and a black matrix 404.

Among them, a layer of red color conversion material is coated on the light-emitting area 2 where the red light needs to be emitted to form the red color resist 401, the red color resist 401 may include red phosphor or red quantum dot material, the red quantum dot material may include cadmium selenide or perovskite or indium phosphide, and the FWHM of the red color resist 401 ranges from 30 nanometers to 50 nanometers.

A layer of green color conversion material is coated on the light-emitting area 2 where the green light needs to be emitted to form the green color resist 402, the green color resist 402 may include green phosphor or green quantum dot material, the green quantum dot material may include cadmium selenide or perovskite or indium phosphide, and the FWHM of the green color resist 402 ranges from 30 nanometers to 50 nanometers.

A layer of transmissive material is coated on the light-emitting area 2 where the blue light needs to be emitted to form the light-transmitting pattern 403, and the transmissive material may include any one of polyacrylate resin, polyimide resin, or silica-based inorganic material. It can be understood that at this time, the light-emitting layer 203 is a blue light emitting layer. The black matrix 404 may be made of a black epoxy resin material.

In the present application, an insulating barrier area 3 is set surrounding the light-emitting area 2, and the insulating layer 205 in the insulating barrier area 3, the second electrode 30, and the integrated circuit substrate 10 are used to jointly define the position of the light-emitting device 4. There is no need to use an etching process to form a step structure to achieve the positioning of the light-emitting device 4, which avoids the side wall of the step structure being damaged by over-etching, resulting in an increase in the lateral leakage current, thereby reducing the lateral leakage current and improving the luminous efficiency of the display panel 1.

At the same time, since the insulating barrier area 3 is formed by implanting ions that increase resistance, the insulating barrier area 3 can be made very small, thereby reducing the distance between adjacent two light-emitting devices 4 and improving the pixel density of the device.

In the present application, a whole-surface light-emitting device layer 20 is used to bond with the integrated circuit substrate 10, and then defines the position of the light-emitting device 4 through the insulating barrier area 3, avoiding the use of high-precision bonding technology, which not only reduces costs but also improves yield.

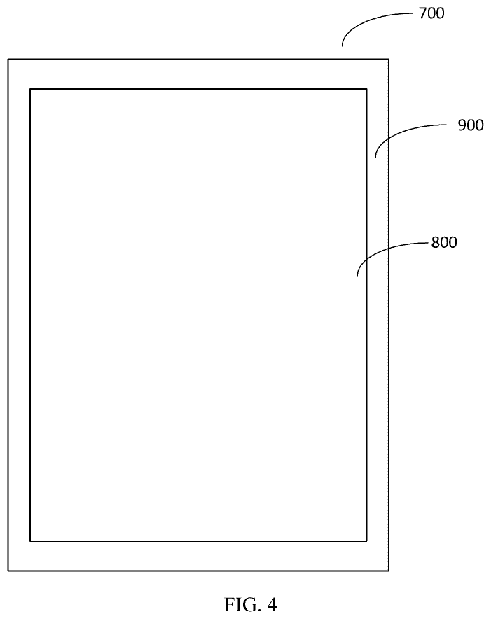

The present application also provides a display module and a terminal device, both of which include the above-mentioned display panel which will not be repeated here. As shown in FIG. 4, a terminal device 700 includes a display panel 800 and a frame 900. The display module further includes at least one of a back plate, a cover plate, an optical film, and a polarizer, and the terminal device includes but is not limited to a mobile phone, a laptop computer, and a tablet computer.

The display panel provided according to the embodiments of the present application includes an integrated circuit substrate, a light-emitting device layer, and a second electrode. The integrated circuit substrate includes a first substrate, a plurality of first electrodes arranged at intervals on the first substrate, the light-emitting device layer is disposed on the integrated circuit substrate and includes a light-emitting area and an insulating barrier area which are arranged at intervals. The light-emitting device layer further includes a light-emitting device disposed in the light-emitting area, the light-emitting device includes a bonding metal layer, a first doped semiconductor layer, a light-emitting layer, and a second doped semiconductor layer sequentially stacked on the integrated circuit substrate. The first electrode is electrically connected to the bonding metal layer, the second electrode is disposed on a side of the light-emitting device layer away from the first substrate, the material of the second electrode is a transparent material, and the second electrode is electrically connected to the light-emitting device. In the insulating barrier area, the light-emitting device layer is provided with an insulating layer, the insulating layer is disposed surrounding the light-emitting device, the two ends of the insulating layer are respectively connected to the second electrode and the integrated circuit substrate to form a closed accommodating chamber, the light-emitting device is disposed in the closed accommodating chamber, and the adjacent two light-emitting devices are insulated. The insulating barrier area is disposed surrounding the light-emitting area, the insulating layer for insulating adjacent two light-emitting devices is provided in the insulating barrier area, the two ends of the insulating layer are respectively connected to the second electrode and the integrated circuit substrate to form a closed accommodating chamber, the position of the light-emitting device is defined by the closed accommodating chamber, the insulating layer can reduce the lateral leakage current between the adjacent two light-emitting devices, thereby improving the luminous efficiency of the display panel.

Some embodiments of the present application have been described in detail above. The description of the above embodiments merely aims to help to understand the present application. Many modifications or equivalent substitutions with respect to the embodiments may occur to those of ordinary skill in the art based on the present application. Thus, these modifications or equivalent substitutions shall fall within the scope of the present application.

What is claimed is:

1. A display panel, comprising:
an integrated circuit substrate comprising a first substrate and a plurality of first electrodes arranged at intervals on the first substrate;
a light-emitting device layer disposed on the integrated circuit substrate and having a plurality of light-emitting areas arranged in an array and a plurality of insulating barrier areas each disposed between two adjacent ones of the light-emitting areas, the light-emitting device layer comprising a plurality of light-emitting devices each disposed in one of the light-emitting areas and electrically connected to one of the first electrodes; and
a second electrode disposed on a side of the light-emitting device layer away from the first substrate and electrically connected to the light-emitting devices,
wherein a plurality of insulating layers are disposed respectively in the insulating barrier areas; and
each of the insulating layers has opposite ends respectively connected to the second electrode and the integrated circuit substrate, and each of the light-emitting devices is surrounded by ones of the insulating layers, so that the ones of the insulating layers, the second electrode and the integrated circuit substrate together form a closed accommodating chamber for accommodating the each of the light-emitting devices, and every two adjacent ones of the light-emitting devices are insulated from each other.

2. The display panel according to claim 1, wherein a ratio of a width of each of the insulating barrier areas to a width of each of the light emitting areas ranges from 2:9 to 4:9.

3. The display panel according to claim 1, further comprising:
a plurality of bonding metal layers disposed on the integrated circuit substrate and respectively in the light-emitting areas; and
a filter layer disposed on a side of the second electrode away from the light-emitting device layer,
wherein each of the light-emitting devices comprises a first doped semiconductor layer, a light-emitting layer and a second doped semiconductor layer sequentially stacked on one of the bonding metal layers;
the filter layer comprises a black matrix and a plurality of filter patterns arranged at intervals in the black matrix; and
the light-emitting layer is a white light emitting layer, and the filter patterns comprise a red color resist, a green color resist and a blue color resist arranged at intervals.

4. The display panel according to claim 1, further comprising:
a plurality of bonding metal layers disposed on the integrated circuit substrate and respectively in the light-emitting areas; and
a filter layer disposed on a side of the second electrode away from the light-emitting device layer,
wherein each of the light-emitting devices comprises a first doped semiconductor layer, a light-emitting layer and a second doped semiconductor layer sequentially stacked on one of the bonding metal layers;
the filter layer comprises a black matrix and a plurality of filter patterns arranged at intervals in the black matrix; and
the light-emitting layer is a blue light emitting layer, the filter patterns comprise a red color resist, a green color resist and a light-transmitting pattern arranged at intervals, and the light-transmitting pattern is made of a transparent material.

5. The display panel according to claim 4, wherein each of the filter patterns is disposed opposite to one of the light-emitting devices; and
the black matrix comprises a plurality of black blocks, and an orthographic projection of each of the black blocks on the first substrate overlaps an orthographic projection of one of the insulating layers on the first substrate.

6. The display panel according to claim 5, wherein each of the bonding metal layers comprises a first portion abutting against the integrated circuit substrate and a second portion abutting against the light-emitting device layer, and the first portion and the second portion are made of a same material.

7. The display panel according to claim 4, wherein every two adjacent ones of the bonding metal layers are insulated from each other;
the first doped semiconductor layer of one of the every two adjacent ones of the light-emitting devices is insulated from the first doped semiconductor layer of another one of the every two adjacent ones of the light-emitting devices;
the light-emitting layer of the one of the every two adjacent ones of the light-emitting devices is insulated from the light-emitting layer of the another one of the every two adjacent ones of the light-emitting devices; and
the second doped semiconductor layer of the one of the every two adjacent ones of the light-emitting devices is insulated from the second doped semiconductor layer of the another one of the every two adjacent ones of the light-emitting devices.

8. The display panel according to claim 4, wherein each of the insulating layers is formed by implanting ions into the light-emitting device layer.

9. The display panel according to claim 8, wherein each of the insulating layers comprises at least one of helium ions, carbon ions, nitrogen ions, oxygen ions, or fluorine ions.

10. The display panel according to claim 4, wherein a first periodic stress adjustment layer and a first current diffusion layer are disposed between the first doped semiconductor layer and the light-emitting layer;
a second periodic stress adjustment layer and a second current diffusion layer are disposed between the second doped semiconductor layer and the light-emitting layer;
the first periodic stress adjustment layer and the second periodic stress adjustment layer are configured to reduce stress inside the light-emitting device layer; and
the first current diffusion layer is configured to reduce a contact resistance between the first doped semiconductor layer and the light-emitting layer, and the second current diffusion layer is configured to reduce a contact resistance between the second doped semiconductor layer and the light-emitting layer.

11. A method of manufacturing the display panel of claim 1, comprising:
providing the integrated circuit substrate and the light-emitting device layer, wherein the integrated circuit substrate comprises the first substrate and the plurality of first electrodes arranged at intervals on the first substrate;
forming a first bonding layer on a surface of the integrated circuit substrate and a second bonding layer on a surface of the light-emitting device layer, and bonding the first bonding layer and the second bonding layer to each other to obtain a bonding metal layer;
defining the plurality of light-emitting areas and the plurality of insulating barrier areas of the light-emitting device layer, wherein each of the light-emitting areas is surrounded by ones of the insulating barrier areas;
performing ion implantation on each of the insulating barrier areas from a side of the light-emitting device layer, so that at least respective parts of the light-emitting device layer in the insulating barrier areas are converted into the plurality of insulating layers and the plurality of light-emitting devices respectively disposed in the light-emitting areas are obtained, wherein every two adjacent ones of the light-emitting devices are insulated from each other by one of the insulating layers; and
forming a layer of transparent conductive material on an entire surface of the light-emitting device layer away from the integrated circuit substrate, to obtain the second electrode.

12. A terminal device comprising a display panel, the display panel comprising:
an integrated circuit substrate comprising a first substrate and a plurality of first electrodes arranged at intervals on the first substrate;
a light-emitting device layer disposed on the integrated circuit substrate and having a plurality of light-emitting areas arranged in an array and a plurality of insulating barrier areas each disposed between two adjacent ones of the light-emitting areas, the light-emitting device layer comprising a plurality of light-emitting devices each disposed in one of the light-emitting areas and electrically connected to one of the first electrodes; and
a second electrode disposed on a side of the light-emitting device layer away from the first substrate and electrically connected to the light-emitting devices,
wherein a plurality of insulating layers are disposed respectively in the insulating barrier areas; and
each of the insulating layers has opposite ends respectively connected to the second electrode and the integrated circuit substrate, and each of the light-emitting devices is surrounded by ones of the insulating layers, so that the ones of the insulating layers, the second electrode and the integrated circuit substrate together form a closed accommodating chamber for accommodating the each of the light-emitting devices, and every two adjacent ones of the light-emitting devices are insulated from each other.

13. The terminal device according to claim 12, wherein a ratio of a width of each of the insulating barrier areas to a width of each of the light emitting areas ranges from 2:9 to 4:9.

14. The terminal device according to claim 12, wherein the display panel further comprises:
a plurality of bonding metal layers disposed on the integrated circuit substrate and respectively in the light-emitting areas; and a filter layer disposed on a side of the second electrode away from the light-emitting device layer;
each of the light-emitting devices comprises a first doped semiconductor layer, a light-emitting layer and a second doped semiconductor layer sequentially stacked on one of the bonding metal layers;
the filter layer comprises a black matrix and a plurality of filter patterns arranged at intervals in the black matrix; and
the light-emitting layer is a white light emitting layer, and the filter patterns comprise a red color resist, a green color resist and a blue color resist arranged at intervals.

15. The terminal device according to claim 12, wherein the display panel further comprises:
a plurality of bonding metal layers disposed on the integrated circuit substrate and respectively in the light-emitting areas; and a filter layer disposed on a side of the second electrode away from the light-emitting device layer;
each of the light-emitting devices comprises a first doped semiconductor layer, a light-emitting layer and a second doped semiconductor layer sequentially stacked on one of the bonding metal layers;
the filter layer comprises a black matrix and a plurality of filter patterns arranged at intervals in the black matrix; and
the light-emitting layer is a blue light emitting layer, the filter patterns comprise a red color resist, a green color resist and a light-transmitting pattern arranged at intervals, and the light-transmitting pattern is made of a transparent material.

16. The terminal device according to claim 15, wherein each of the filter patterns is disposed opposite to one of the light-emitting devices; and
the black matrix comprises a plurality of black blocks, and an orthographic projection of each of the black blocks on the first substrate overlaps an orthographic projection of one of the insulating layers on the first substrate.

17. The terminal device according to claim 16, wherein each of the bonding metal layers comprises a first portion abutting against the integrated circuit substrate and a second portion abutting against the light-emitting device layer, and the first portion and the second portion are made of a same material.

18. The terminal device according to claim 15, wherein each of the insulating layers is formed by implanting ions into the light-emitting device layer.

19. The terminal device according to claim 18, wherein each of the insulating layers comprises at least one of helium ions, carbon ions, nitrogen ions, oxygen ions, or fluorine ions.

20. The terminal device according to claim 15, wherein a first periodic stress adjustment layer and a first current diffusion layer are disposed between the first doped semiconductor layer and the light-emitting layer;
a second periodic stress adjustment layer and a second current diffusion layer are disposed between the second doped semiconductor layer and the light-emitting layer;
the first periodic stress adjustment layer and the second periodic stress adjustment layer are configured to reduce stress inside the light-emitting device layer; and
the first current diffusion layer is configured to reduce a contact resistance between the first doped semiconductor layer and the light-emitting layer, and the second current diffusion layer is configured to reduce a contact resistance between the second doped semiconductor layer and the light-emitting layer.
